(19) United States
(12) Patent Application Publication
(10) Pub. No.: US 2012/0312353 A1
(43) Pub. Date: Dec. 13, 2012

(54) SEMICONDUCTOR COMPONENT HAVING DIAMOND-CONTAINING ELECTRODES AND USE THEREOF

(75) Inventors: Joachim Kusterer, Weisshorn-Oberhausen (DE); Erhard Kohn, Ulm (DE)

(73) Assignee: Universitaet Ulm, Ulm (DE)

(21) Appl. No.: 13/384,070

(22) PCT Filed: Jul. 19, 2010
(86) PCT No.: PCT/EP10/04393

§ 371 Date: Aug. 6, 2012

(30) Foreign Application Priority Data
Jul. 17, 2009 (DE) 10 2009 033 652.4

(51) Int. Cl. H01L 31/0224

(52) U.S. Cl. 136/249

(57) ABSTRACT

A semiconductor component includes at least one electrode arrangement, the electrode arrangement having at least two electrodes, at least one electrode of which is an electrode including diamond. The semiconductor component has at least one monolithically integrated solar cell as energy source for the at least one electrode arrangement. The semiconductor component may be used for example in hydrogen production by electrolysis, in electroanalysis and also in water treatment.

### RELATED APPLICATIONS

This application is a national phase application of PCT/EP2010/004393, internationally filed on Jul. 19, 2010, and is filed pursuant to 35 U.S.C. § 371, which also claims priority to German Application No. 10 2009 033 652.4, filed Jul. 17, 2009, which applications are incorporated by reference herein in their entirety.

### TECHNICAL FIELD

The invention relates to a semiconductor component which includes at least one electrode arrangement, the electrode arrangement having at least two electrodes, at least one electrode of which is an electrode including diamond. Furthermore, the semiconductor component has at least one monolithically integrated solar cell as energy source for the at least one electrode arrangement. The semiconductor component according to the invention is used for example in hydrogen production by electrolysis, in electroanalysis and also in water treatment.

### BACKGROUND

Diamond electrodes have been used for many years in electroanalysis and water treatment. Investigation of electrode properties thereby includes in particular the anode region for trace analysis and detection of biomolecules and oxidation of toxic materials. Nanocrystalline diamond thin-films which are deposited on foreign materials, such as Si, are thereby generally used. Electrode arrangements for trace analysis are generally electrode arrays, both the active electrode and the counter-electrode including highly-doped diamond and then being double electrode structures. Electrode arrangements for water treatment naturally have a large surface area and therefore may include poly- or nanocrystalline diamond.

Diamond is well suited to hydrogen production since, due to the high quasi-metallic boron doping, the hydrogen production at the cathode is catalytically assisted (Yu Kai et al., “Hydrogen Evolution on Diamond Electrodes by the Volmer-Heyrovsky Mechanism”, J. Electrochem. Soc. 154, (2007), F36-F43). All investigations confirm that diamond is inert in aqueous solution. Defect structures can only be etched-out in highly-oxidised acids. Due to the high electrochemical quality, hard-bonded (small-angle) particle boundaries are required. This delimits the particle size at the bottom to the range above about 50 nm so that UNCD (ultrananocrystalline diamond with average particle sizes between 2 and 10 nm) are only partially suitable.

For electroanalytical applications, the diamond surface can be functionalized electrochemically, e.g. via nanospots. This is, for example, described in DE 10 2007 039 706.4 for an ISFET structure which likewise has two planar source- and drain contacts.

The electrode arrangements known to date from the state of the art have not to date been transparent since they are based on layers which are highly-doped with boron with thicknesses in the μm range. In addition, they are generally deposited on non-transparent substrates, such as Si. They are thus not able to be integrated vertically above a solar cell. For applications in biochemistry, diamond surfaces terminated with hydrogen are used on glass substrates, in order to allow fluorescence investigations. The surface which is saturated with hydrogen is however not corrosion-resistant.

For application in hydrogen production, sufficiently large surfaces are necessary, which are at present not available by means of monocrystalline diamond substrates or diamond quasi-substrates. Diamond monocrystals are at present limited to an area of about 1 cm². The only method known at present of producing free-standing diamond films (quasi-substrates is deposition on Ir, which, however, is not yet possible on a large scale and appears uneconomical. Therefore the relevant large-scale approach is the use of polycrystalline or nanocrystalline layers on transparent foreign substrates. Polycrystalline free-standing substrates (quasi-substrates) are used, highly-polished on both sides, as heat sinks and can be used here also as quasi-substrates.

Foreign substrates are SiO₂ or Al₂O₃ (sapphire) or other high-melting and transparent dielectrics. Diamond must be grown thereon via a nucleation layer. For this purpose, two configurations are customary: seeding via deposited diamond nanopowder or nucleation on Si or a carbide-forming metal with an applied electrical field (bias enhanced nucleation, BEN).

A highly-transparent and simultaneously corrosion-resistant diamond electrode arrangement can serve at the same time as covering for the solar cell. Hence such solar cells can be used in corrosive environments, such as sea water, for hydrogen production or water treatment, such as desalination. A hybrid integration technique, e.g. by means of a transparent adhesive compound, such as by using PDMS, is readily conceivable.

The monolithic vertical integration of the diamond cover electrode arrangement with a solar cell depends upon whether the solar cell structure can tolerate diamond being grown thereon. This is only partially possible for the systems used to date. Growing diamond of high electrochemical quality thereon must be effected at high temperature in a highly-reducing H-atmosphere. In order to obtain electrochemical diamond layer quality, the growing temperature must be above 600° C., best at about 700° C. The atmosphere is almost pure hydrogen (>97% H-content in the growing environment). Thus all attempts to date to grow Si, GaAs or GaN directly with high-quality diamond and to obtain the substrate properties have failed (PW. May et al.: “Deposition of CVD diamond onto GaN”; Diamond and Related Materials, 15 (2006); 526-530).

### SUMMARY

Starting herefrom, it was the present invention is directed to making available a semiconductor component which eliminates the problems known from the state of the art and ensures an efficient energy supply.

According to the invention, a semiconductor component is made available which has at least one electrode arrangement having at least two electrodes, at least one electrode of which is an electrode including diamond. Furthermore, the semiconductor component has at least one monolithically integrated solar cell as energy source for the at least one electrode arrangement.

Hence a vertical stack arrangement, which has an electrode including diamond and a solar cell arrangement for internal inherent energy supply, is made available. The semiconductor component according to the invention is thereby particularly suitable for use in hydrogen production by electrolysis, in electroanalysis and water treatment. The production of hydrogen by decomposition of water is an important form of energy storage. Hydrogen can thereby be produced by direct decomposition of water by hydrolysis in an aqueous environment, hydrogen being released at the cathode and oxygen at the anode.

The diamond electrode structure consists of two laterally oppositely-situated quasi-metallic conductive and hence highly-doped and advantageously thin and hence transparent diamond contacts (double electrode arrangement) on an advantageously transparent insulating substrate (which can also be diamond). One contact thereby serves as cathode, the other as anode or as operating electrode and counter-electrode. The voltage which is necessary for operation is produced internally by the solar cell which is vertically integrated with the electrode. This solar cell can be integrated in a hybrid or monolithic manner.

Normally, in the case of the mentioned spheres of use, either inert noble metals, such as Pt or Au, are used as electrode materials, which are not transparent, have a small electrochemical potential window and the electrochemical activity of which is greatly dependent upon the electrolyte environment. On the other hand, metal oxides can be used which can indeed be transparent, but must be reduced cathodically and periodically oxidized and hence must always undergo a regeneration process.

According to the invention, now a planar diamond double electrode structure with at least two oppositely-situated contacts on a common substrate is proposed, at least one contact functioning as cathode and the other as anode.

In this respect, diamond offers the advantage that it is inert and therefore does not take part in the reaction, i.e. the electrolysis. Furthermore, diamond is not etched and does not corrode. Since diamond concerns a semiconductor with a high band gap, the electrode arrangement can be extended with detector structures based on diamond- and heterostructures and also transistor structures (ISFETs).

The electrochemical window for H₂O decomposition in a diamond electrode is about ΔV=3.0 V. If a voltage greater than ΔV (the electrochemical potential window) (e.g. 5 V) is applied to a planar contact arrangement, a current begins to flow between the contacts via the electrolyte by direct electron transfer across the diamond-electrolyte interface. Since diamond in a wet chemical environment is itself inert under high cathodic and anodic overpotentials, the electrode surface can also be used in salt water and contaminated water and hence e.g. for water treatment, i.e. the diamond must be of high electrochemical quality. This is the case inter alia for monocrystalline, polycrystalline and nanocrystalline material with low particle boundary content. A high electrochemical quality is distinguished firstly by the high inertness and resistance to etching which has been mentioned several times above, but also by large electrolytic potential windows and a low background current in the electrolytic window.

Both conventional layer structures made of Si, III-V semiconductors, organic semiconductors or other materials are used as solar cell arrangements, provided they are integrated in a hybrid manner, e.g. by gluing. In order to achieve the water decomposition voltage of the diamond electrode arrangement (when used in hydrogen production), possibly a series circuit of a plurality of cells is necessary. In some embodiments, the monolithic coating with a polar InGaN solar cell heterostructure is based on GaN. InGaN solar cells can be adapted efficiently to the solar spectrum via a variation in the In content, and hence can have high efficiency. High terminal voltage can be produced via the band gap and, via heterostructures, such as with an InAlN cover layer, high polarization-induced two-dimensional interface charge densities (2DEG and 2DHG) which can serve as low-ohmic contact layers can be produced.

The voltage ΔV is produced by illumination of a vertically integrated solar cell itself. Therefore 2 configurations are preferred for the electrode/solar cell stack:

In the first configuration, the solar cell is illuminated directly and the electrode arrangement with diamond electrode is disposed on the rear-side.

In the second configuration, the electrode arrangement with diamond electrode is situated on the solar cell surface.

In both arrangements according to the invention, it can be advantageous to insert a third component as intermediate plane between both parts. In the case where the solar cell is disposed at the top, this can be a reflection layer for radiation which is not directly absorbed in the solar cell, or an electrical CMOS circuit for signal processing in electroanalytical applications. In the arrangement with the electrode on the upper-side, an optical microlens array could be integrated, in order to increase the efficiency of the solar cell.

In the first arrangement according to the invention, the solar cell is situated on the radiation rear-side. The rear-side of the solar cell must be connected securely to the rear-side of the electrode. This is readily conceivable by gluing or soldering. Also, as described above, an intermediate plane can be inserted. It can also be advantageous if solar cell and diamond electrode are situated on a common substrate. Al₂O₃ (sapphire) is possible as such. On sapphire, both a solar cell based on GaN can be grown epitaxially and diamond can be deposited via a nucleation intermediate layer.

In this arrangement, the generated gas flow is diverted sideways, which can lead to self-passivation of the reaction, if the forming bubbles cannot be continually removed. This is true in particular for hydrogen generation but also for the gaseous reaction products in electroanalytical applications or water treatment. Therefore further components, such as mirrors or capillaries, must generally be integrated in this arrangement.

In the second arrangement according to the invention, the diamond electrode arrangement is disposed on the solar cell and therefore must be highly transparent, diamond fulfilling this condition as a semiconductor with a high band gap and therefore high transparency up to the UV range (225 nm). Diamond is furthermore chemically inert, corrosion-resistant and is not etched in aqueous solutions and is therefore the only inert semiconductor electrode material. It is therefore also an ideal covering of the solar cell and an ideal protection against corrosion. Nevertheless, diamond as electrochemical electrode must have quasi-metallic conductivity and therefore must be highly doped (>10²⁰ cm⁻³). A doping agent used for this purpose is boron. As a result, diamond is however absorbing in specific wavelength ranges. In order nevertheless to be highly transparent for incident sunlight, the conductive electrode layer must be substantially thinner than the absorption coefficient, i.e. in the sub-μm or nm range. Such thin doping layers are known as delta- or pulse-doping profiles.

The diamond electrode arrangement and solar cell can be integrated in a hybrid manner, e.g. by means of transparent and reflection-free gluing. Then there are no restrictions on the materials of the solar cell, as long as they are suitable for the bonding technique. Monolithic integration is advantageous however with a solar cell based on GaN, such as an InGaN cell. The active InGaN layer sequence is generally grown epitaxially on GaN. Nevertheless, growing of diamond on such a solar cell based on GaN is difficult since the diamond growth (for material of high electrochemical quality) must be effected at a high temperature (above 600° C.) in a highly-reducing hydrogen atmosphere. GaN is thereby generally degraded. The degradation can be suppressed by covering the GaN- (or InGaN-) surface by InAlN. If thus an nm-thin InAlN cover layer is grown on the surface of the solar cell, diamond can be deposited thereon. This is effected in general via a nucleation intermediate layer.

The subsequent embodiments represent advantageous developments of the semiconductor component according to the invention.

In some embodiments, at least one electrode arrangement is disposed on the side of the at least one solar cell, which side is orientated towards the incident light, the electrode arrangement being transparent for wavelengths in the UV-VIS range.

In some embodiments, the at least one electrode arrangement is disposed on the side of the at least one solar cell, which side is orientated away from the incident light.

In some embodiments, the electrode including diamond consists, at least in regions, of doped diamond or essentially includes this. In some embodiments, the diamond is quasi-metallic, in particular doped with boron, the concentration of the doping agent being in the range of 8*10¹⁹ to 10²² cm⁻³.

In some embodiments, the quasi-metallically doped regions of the electrode including diamond are configured as a layer.

In some embodiments, this layer has a layer thickness in the range of 1 nm to 5 μm. In some embodiments, the layer has a thickness in the range of 1 nm to 500 nm. In some embodiments, the layer has a thickness in the range of 1 nm to 50 nm.

In some embodiments, the at least one electrode including diamond is functionalized, at least in regions, with metallic nanodots. In some embodiments, the nanodots are made of gold. Because of the smaller size of the nanodots, transparency of >90% can be achieved.

According to the invention, it is necessary that at least one electrode is an electrode including diamond. In some embodiments, both electrodes are electrodes including diamond.

In some embodiments, one electrode is an electrode including diamond and the second electrode is a non-transparent material, in particular platinum.

In some embodiments, the electrode arrangement has an electrochemical potential window of ≧3.0 V at a dark current density I ≦10 μA/mm². In the case of functionalizing with metallic nanodots, as mentioned above, an electrochemical potential window of ≧1.23 V is made possible.

Furthermore, in some embodiments, the at least one solar cell consists of a layer structure based on silicon, a III-V semiconductor or an organic semiconductor, in particular made of InAlN or InGaN. It hereby concerns optically adapted heterostructures.

In some embodiments, the electrode arrangement has at least one insulating layer, in particular made of diamond, Al₂O₃, AlN, SiO₂ or a glass. In some embodiments, the insulating layer consists of a monocrystalline diamond, polycrystalline diamond with a particle size ≧1 μm or of nanocrystalline diamond with a particle size between 5 nm and 1 μm.

In some embodiments, the at least one electrode arrangement and the at least one solar cell are disposed on at least one substrate layer, in particular made of Al₂O₃, AlN, SiC or silicon.

In some embodiments, the semiconductor component has a covering made of a cover layer, in particular made of InAlN, and a diamond nucleation layer. The cover layer made of InAlN is thereby preferably adapted to the substrate layer lattice. With respect to the diamond nucleation layer, it is preferred that this can be used for a “bias-enhanced nucleation” process. Likewise, the diamond nucleation layer should include a high density of deposited nanodiamond nuclei.

In some embodiments, the semiconductor component has at least one further functional layer. There is possible as further functional layer for example an optical microlens array or an optical anti-reflection coating for increasing the efficiency of the solar cell.

It is likewise possible that an electrochemically active transistor based on diamond is integrated in the semiconductor component. There are included here for example ISFETs or ChemFETs. Electronically active transistors based on Si-MOS or thin-film FETs, e.g. based on zinc oxide, can be integrated by introduction of the Si circuit as third component between solar cell and electrode comprising diamond.

Likewise it is possible to effect an integration with an electrochemically active heterostructure transistor (ISFETs or ChemFETs) based on GaN, e.g. with an InAlN barrier layer.

With respect to the contacting of the semiconductor component, the possibilities exist of a direct electrical through-contacting or a peripheral electrical contacting.

With respect to the electrode supply, this may have a covering on the surface which is in contact with the liquid. In some embodiments, this covering consists of an insulating diamond or another dielectric and chemically inert passivation layer or encapsulation. The electrode structure can be configured for example as a large-surface double electrode array, e.g. as an interdigital finger structure with a high optical filling factor.

In some embodiments, the at least one solar cell and the electrode arrangement are connected to each other via a frictional- or integral surface assembly. There are included here gluing, soldering or pressing together. If a hybrid integration is effected by means of gluing, then here a transparent, optically adapted and reflection-free gluing is preferred.

In some embodiments, structuring of the electrode including diamond is effected by selective deposition or selective rear-etching.

In some embodiments, the semiconductor component has a modified or functionalized diamond surface for reducing the electrochemical potential window, this modification or functionalization being able to be effected over the whole surface or by nanospots. Likewise, a specific termination of the diamond surface is possible, in particular for electroanalytical applications, e.g. by hydrogen, fluorine, nitrogen or other chemical elements and compounds.

In some embodiments, the semiconductor component according to the invention is used for hydrogen production by electrolysis, for electroanalysis or for water treatment.

### BRIEF DESCRIPTION OF THE FIGURES

The subject according to the invention is intended to be explained in more detail with reference to the subsequent Figures and the example, without wishing to restrict said subject to the special embodiments shown here.

FIG. 1 shows a first variant according to the invention of the semiconductor component with reference to a schematic representation.

FIG. 2 shows a second variant according to the invention of the semiconductor component with reference to a schematic representation.

### DETAILED DESCRIPTION

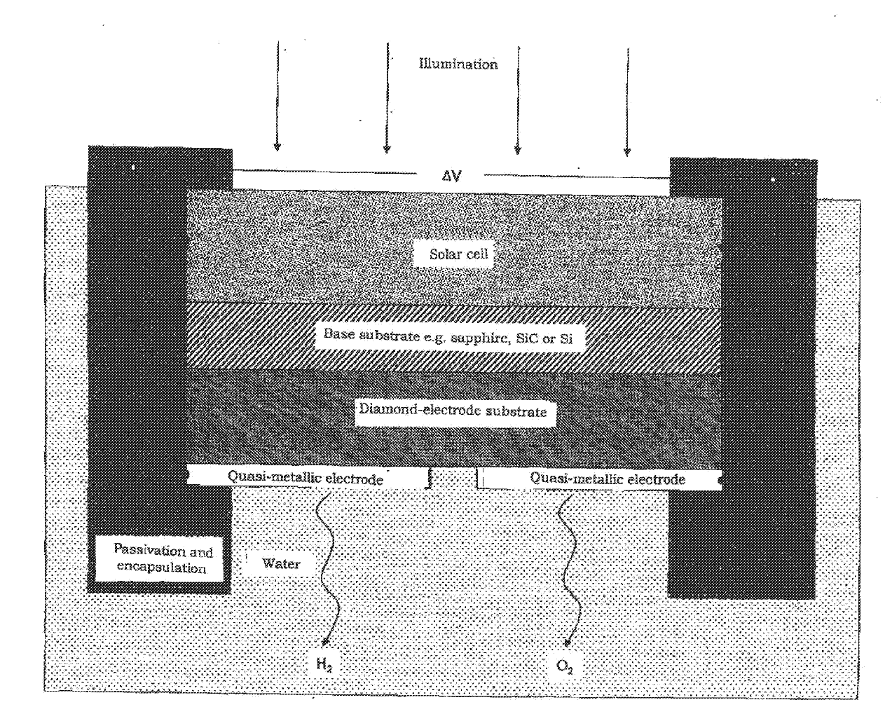

A variant of the semiconductor component 1 according to the invention is represented in FIG. 1, in which the electrode arrangement made of two electrodes (2, 2′) including diamond is disposed on the rear-side relative to the solar cell 3. By rear-side there should be understood here that the electrode arrangement is disposed on the side of the solar cell 3 which is orientated away from the incident light 4. The electrodes 2 and 2′ including diamond are integrated in a diamond-electrode substrate 5 and thus form the electrode arrangement. This can be disposed together with the solar cell 3 on a common base substrate 6, e.g. made of sapphire, SiC or Si. The use for hydrogen generation with a solar cell voltage ΔV which is greater than the electrochemical potential window of the electrode including diamond is represented in FIG. 1. The system described here can therefore in reality also include a series circuit of a plurality of cells.

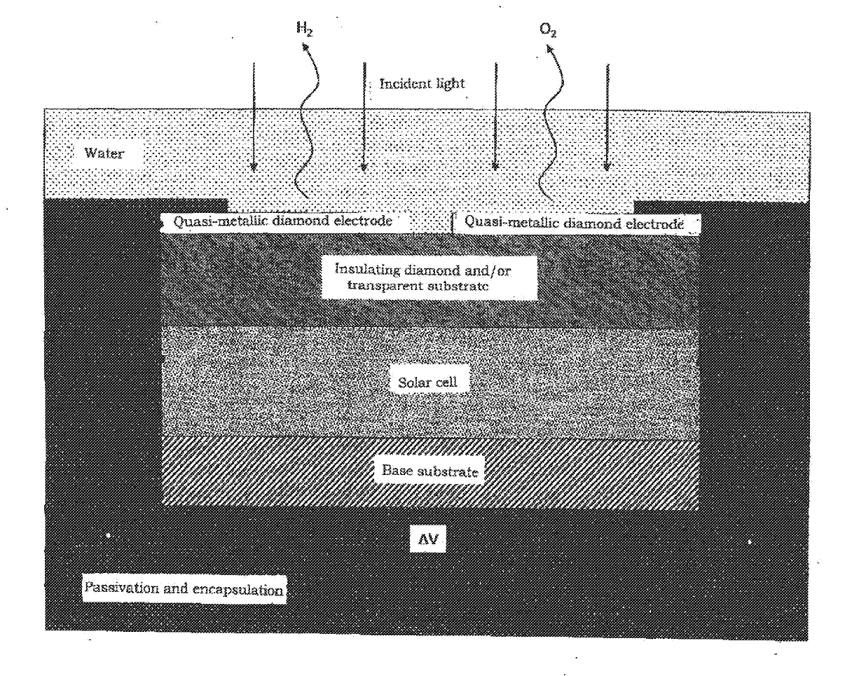

A second variant of the semiconductor component 10 according to the invention, in which the electrode arrangement is disposed on the front-side of the solar cell 11, is represented in FIG. 2. Front-side means here that the electrode arrangement is disposed on the side of the solar cell 11 which is orientated towards the incident light. The electrodes 11 and 11′ including diamond are integrated here in an insulating diamond layer and/or a transparent substrate 13. A basic substrate 14 is disposed on the rear-side of the solar cell. The entire system is integrated in a passivation and encapsulation 15. The system represented here is suited to hydrogen generation with a solar cell voltage ΔV which is greater than the electrochemical potential window of the electrode including diamond. Here also, the system can include a series circuit of a plurality of solar cells.

### EXAMPLE

The starting point for the production of the semiconductor component according to the invention is a carrier substrate made of sapphire or SiC with a polar InGaN solar cell heterostructure based on GaN. This carrier substrate is coated on the rear-side over the entire surface with electrically insulating diamond with the help of chemical vapor deposition. Subsequent thereto, two regions are deposited selectively with conductive diamond, which serve in later application as electrochemical electrodes. These regions are connected respectively via a metallization to the anode and cathode of the solar cell.

Alternatively, also a coating of the solar cell with the electrode arrangement can be effected. The solar cell disposed on the carrier substrate is hereby coated with an insulating diamond layer, on which then conductive regions, e.g. the electrodes including diamond, are produced.

1-21. (canceled)

22. Semiconductor component comprising:
at least one electrode arrangement having at least two electrodes, at least one electrode of which comprises diamond; and
at least one monolithically integrated solar cell as energy source for the at least one electrode arrangement.

23. The semiconductor component according to claim 22, wherein the at least one electrode arrangement is disposed on a side of the at least one solar cell that is orientated towards incident light, the electrode arrangement being transparent for wavelengths in the UV-VIS range.

24. The semiconductor component according to claim 22, wherein the at least one electrode arrangement is disposed on a side of the at least one solar cell that is orientated away from incident light.

25. The semiconductor component according to claim 22, wherein the electrode comprising diamond includes doped diamond.

26. The semiconductor component according to claim 25, wherein the diamond is doped quasi-metallically.

27. The semiconductor component according to claim 25, wherein the doped diamond includes a doping agent at a concentration in the range of 8*10¹⁹ to 10²² cm⁻³.

28. The semiconductor component according claim 25, wherein the doped diamond is present as a layer having a layer thickness of 1 nm to 5 μm.

29. The semiconductor component according to claim 22, wherein the electrode arrangement either has two electrodes comprising diamond, or one electrode comprising diamond and one electrode comprising a non-transparent material.

30. The semiconductor component according to claim 22, wherein the electrode arrangement has an electrochemical potential window of ≧3.0 V at a dark current density I ≦10 μA/mm².

31. The semiconductor component according to claim 29, wherein the at least one electrode comprising diamond or the electrode comprising a non-transparent material is functionalized, at least in regions, with metallic nanodots.

32. The semiconductor component according to claim 31, wherein the electrode arrangement which is functionalized with nanodots has an electrochemical potential window of ≧1.23 V at a dark current density I ≦10 μA/mm².

33. The semiconductor component according to claim 22, wherein the at least one solar cell consists of a layer structure based on silicon, a III-V semiconductor or an organic semiconductor.

34. The semiconductor component according claim 22, wherein the electrode arrangement has at least one insulating layer made from a material selected from the group consisting of diamond, Al₂O₃, AN, SiO₂ and glass.

35. The semiconductor component according claim 34, wherein the insulating layer consists of a material selected from the group consisting of monocrystalline diamond, polycrystalline diamond with a particle size ≧1 μm, and nanocrystalline diamond with a particle size between 5 nm and 1 μm.

36. The semiconductor component according to claim 22, wherein the at least one electrode arrangement and the at least one solar cell are disposed on at least one substrate layer made from a material selected from the group consisting of Al₂O₃, AlN, SiC and silicon.

37. The semiconductor component according to claim 22, wherein the semiconductor component has a cover layer and a diamond nucleation layer.

38. The semiconductor component according to claim 22, further comprising at least one further functional layer for increasing the efficiency of the solar cell.

39. The semiconductor component according to one claim 22, wherein an electrochemically active transistor comprising diamond, is integrated in the semiconductor component.

40. The semiconductor component according to claim 22, wherein the at least one solar cell and the electrode arrangement are connected via a frictional- or integral surface assembly.

41. The semiconductor component according to claim 22, wherein the at least one solar cell comprises at least two solar cells that are connected in series in a planar arrangement.
